(19) United States
(12) Patent Application Publication
(10) Pub. No.: US 2025/0007493 A1
(43) Pub. Date: Jan. 2, 2025

(54) ACOUSTIC WAVE DEVICE

(71) Applicant: Murata Manufacturing Co., Ltd., Nagaokakyo-shi (JP)

(72) Inventor: Sho NAGATOMO, Nagaokakyo-shi (JP)

(21) Appl. No.: 18/884,559

(22) Filed: Sep. 13, 2024

Related U.S. Application Data
(63) Continuation of application No. PCT/JP2023/012754, filed on Mar. 29, 2023.
(60) Provisional application No. 63/324,849, filed on Mar. 29, 2022.

(51) Int. Cl. H03H 9/13; H03H 9/02; H03H 9/56

(52) U.S. Cl. CPC H03H 9/132; H03H 9/02015; H03H 9/566

(57) ABSTRACT

An acoustic wave device includes a piezoelectric layer including first and second main surfaces, first and second electrode fingers on the first main surface and respectively connected to an input potential and an output potential, and a third electrode finger on at least one of the first and second main surfaces and connected to a reference potential. The first and second electrode fingers when seen from an electrode finger orthogonal direction orthogonal or substantially orthogonal to a direction in which the first and second electrode fingers extend. A region where the first and second electrode fingers overlap in the electrode finger orthogonal direction is a facing region. The third electrode finger overlaps with at least a portion of at least one facing region when seen from a main surface facing direction in which the first and second main surfaces face each other.

### CROSS REFERENCE TO RELATED APPLICATIONS

This application claims the benefit of priority to Provisional Application No. 63/324,849 filed on Mar. 29, 2022 and is a Continuation Application of PCT Application No. PCT/JP2023/012754 filed on Mar. 29, 2023. The entire contents of each application are hereby incorporated herein by reference.

### BACKGROUND OF THE INVENTION

### 1. Field of the Invention

The present invention relates to acoustic wave devices.

### 2. Description of the Related Art

Conventionally, an acoustic wave device is widely used for, e.g., a filter in a mobile phone.

In recent years, acoustic wave devices that use a bulk wave in thickness-shear mode, such as the one described in U.S. Pat. No. 10,491,192, have been proposed. In this acoustic wave device, a piezoelectric layer is provided on a support body. A pair of electrodes are provided on the piezoelectric layer. The pair of electrodes face each other on the piezoelectric layer and are connected to potentials different from each other. A bulk wave in thickness-shear mode is excited by application of alternating-current voltage between the above-described electrodes.

An acoustic wave device is, for example, an acoustic wave resonator and is used for, for example, a ladder filter. In order for the ladder filter to obtain favorable characteristics, the electrostatic capacitance ratio plurality of acoustic wave resonators needs to be large. In this case, the electrostatic capacitances of some of the acoustic wave resonators in the ladder filter need to be increased.

Increasing the electrostatic capacitance of an acoustic wave resonator requires, for example, increasing the size of the acoustic wave resonator. Thus, in a case where the acoustic wave resonator is used in a ladder filter, the ladder filter tends to be large in size. A ladder filter increases in size particularly when the ladder filter has an acoustic wave resonator that uses a bulk wave in thickness-shear mode, which has a small electrostatic capacitance.

### SUMMARY OF THE INVENTION

Example embodiments of the present invention provide acoustic wave devices that, when included in filter devices, are each able to obtain favorable filter waveforms without a size increase.

An acoustic wave device according to an example embodiment of the present invention includes a piezoelectric layer including a first main surface and a second main surface facing each other, at least one first electrode finger on the first main surface of the piezoelectric layer and connected to an input potential, at least one second electrode finger on the first main surface of the piezoelectric layer and connected to an output potential, and at least one third electrode finger on at least one of the first main surface and the second main surface of the piezoelectric layer and connected to a reference potential. The first electrode finger and the second electrode finger face each other when seen from an electrode finger orthogonal direction orthogonal or substantially orthogonal to a direction in which the at least one first electrode finger and the at least one second electrode finger extend. A region where the at least one first electrode finger and the at least one second electrode finger adjacent to each other overlap in the electrode finger orthogonal direction is a facing region, and the third electrode finger overlaps with at least portion of at least one facing region when seen from a main surface facing direction in which the first main surface and the second main surface of the piezoelectric layer face each other.

Example embodiments of the present invention provide acoustic wave devices that, when used in filter devices, are each able to obtain favorable filter waveforms without a size increase.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic elevational cross-sectional view of an acoustic wave device according to a first example embodiment of the present invention.

FIG. 2 is a schematic plan view showing an electrode structure of the acoustic wave device according to the first example embodiment of the present invention.

FIG. 3 is a schematic elevational cross-sectional view showing an area around first to third electrode fingers in the first example embodiment of the present invention.

FIG. 4 is a schematic plan view of an acoustic wave device of a comparative example.

FIG. 5 is a diagram showing an example relationship between the electrostatic capacitance and the area of excitation regions in the comparative example.

FIG. 6 is a diagram showing the bandpass characteristics and reflection characteristics of the acoustic wave device according to the first example embodiment of the present invention.

FIG. 7 is a diagram showing the relationship between the center-to-center distance between adjacent electrode fingers and the bandpass characteristics in the first example embodiment of the present invention.

FIG. 8 is a schematic plan view showing the electrode structure of an acoustic wave device according to a modification of the first example embodiment of the present invention.

FIG. 9 is a schematic elevational cross-sectional view showing an area around first to third electrode fingers in a second example embodiment of the present invention.

FIG. 10 is a schematic elevational cross-sectional view showing an area around first to fifth electrode fingers in a third example embodiment of the present invention.

FIG. 11 is a schematic bottom view showing an electrode structure on a second main surface of a piezoelectric layer in the third example embodiment of the present invention.

FIG. 12 is a circuit diagram of an acoustic wave filter device according to a fourth example embodiment of the present invention.

FIG. 13A is a schematic perspective view showing the external appearance of an acoustic wave device that uses a bulk wave in thickness-shear mode, and FIG. 13B is a plan view showing an electrode structure at the piezoelectric layer.

FIG. 14 is a sectional view of a portion taken along the line A-A in FIG. 13A.

FIG. 15A is a schematic elevational cross-sectional view illustrating a Lamb wave propagating in a piezoelectric film in an acoustic wave device, and FIG. 15B is a schematic elevational cross-sectional view illustrating a bulk wave in thickness-shear mode propagating in a piezoelectric film in an acoustic wave device.

FIG. 16 is a diagram showing an amplitude direction of a bulk wave in thickness-shear mode.

FIG. 17 is a diagram showing the resonance characteristics of an acoustic wave device that uses a bulk wave in thickness-shear mode.

FIG. 18 is a diagram showing the relationship between the fractional bandwidth as a resonator and d/p where p is the center-to-center distance between adjacent electrodes and d is the thickness of the piezoelectric layer.

FIG. 19 is a plan view of an acoustic wave device that uses a bulk wave in thickness-shear mode.

FIG. 20 is a diagram showing the resonance characteristics of an acoustic wave device of a reference example in which a spurious mode appears.

FIG. 21 is a diagram showing the relationship between the fractional bandwidth and the magnitude of a spurious mode, i.e., the amount of phase rotation of spurious impedance normalized by about 180°.

FIG. 22 is a diagram showing the relationship between d/2p and a metallization ratio MR.

FIG. 23 is a diagram showing the map of the fractional bandwidth in relationship to the Euler angles (0°, θ, ψ) of LiNbO₃ when d/p is brought to almost zero.

FIG. 24 is a partially cut-away perspective view illustrating an acoustic wave device that uses a Lamb wave.

### DETAILED DESCRIPTION OF THE EXAMPLE EMBODIMENTS

With reference to the drawings, the present invention is disclosed below by describing specific example embodiments of the present invention.

Each example embodiment described herein is exemplary, and configurations in different example embodiments can be partially replaced or combined.

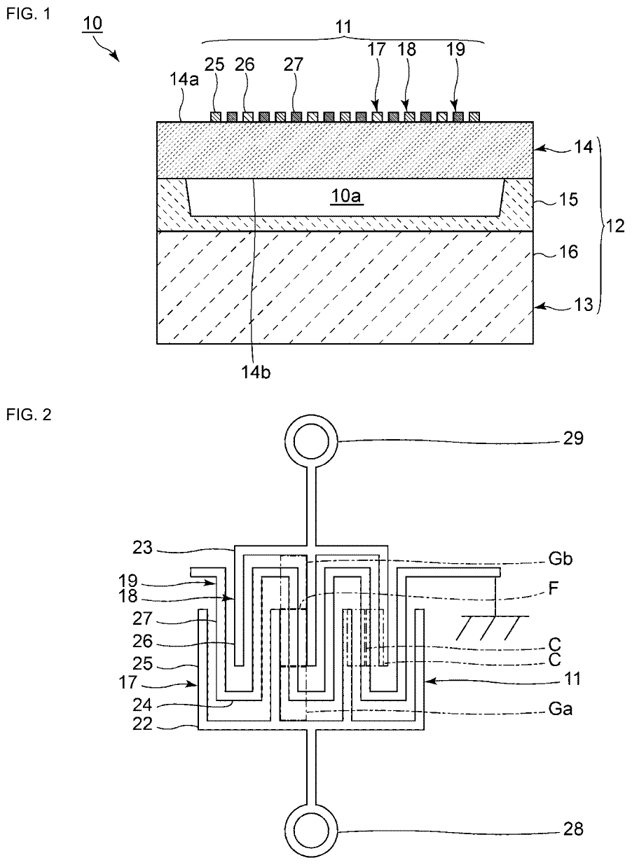

FIG. 1 is a schematic elevational cross-sectional view of an acoustic wave device according to a first example embodiment of the present invention. FIG. 2 is a schematic plan view showing an electrode structure of the acoustic wave device according to the first example embodiment.

An acoustic wave device 10 shown in FIG. 1 is an acoustic wave resonator configured to be able to use thickness-shear mode. In addition, the acoustic wave device 10 is an acoustic-coupling filter. The configuration of the acoustic wave device 10 is described below.

The acoustic wave device 10 includes a piezoelectric substrate 12 and a functional electrode 11. The piezoelectric substrate 12 includes a support 13 and a piezoelectric layer 14. In the present example embodiment, the support 13 includes a support substrate 16 and an insulating layer 15. The insulating layer 15 is provided on the support substrate 16. The piezoelectric layer 14 is provided on the insulating layer 15. The support 13 may include only the support substrate 16.

The piezoelectric layer 14 includes a first main surface 14a and a second main surface 14b. The first main surface 14a and the second main surface 14b face each other. Of the first main surface 14a and the second main surface 14b, the second main surface 14b is located on the support 13 side. In the present example embodiment, the functional electrode 11 is provided on the first main surface 14a of the piezoelectric layer 14. Of the first main surface 14a and the second main surface 14b, the first main surface 14a may be located at the support 13 side. In this case, the functional electrodes 11 may be provided on the first main surface 14a.

As shown in FIG. 2, the functional electrode 11 includes a pair of comb-shaped electrodes and a reference potential electrode 19. The reference potential electrode 19 is connected to a reference potential. The pair of comb-shaped electrodes are, specifically, a first comb-shaped electrode 17 and a second comb-shaped electrode 18. The first comb-shaped electrode 17 is connected to an input potential. More specifically, the first comb-shaped electrode 17 is connected to the input potential via an input terminal 28. Meanwhile, the second comb-shaped electrode 18 is connected to an output potential. More specifically, the second comb-shaped electrode 18 is connected to the output potential via an output terminal 29. The input terminal 28 and the output terminal 29 may be configured as electrode pads or may be configured as wiring, for example.

The first comb-shaped electrode 17 is directly connected to the input terminal 28. The first comb-shaped electrode 17 may be connected to the input terminal 28 indirectly via another element. The second comb-shaped electrode 18 is directly connected to the output terminal 29. The second comb-shaped electrode 18 may be connected to the output terminal 29 indirectly via another element. The first comb-shaped electrode 17 may be connected to the output potential, and the second comb-shaped electrode 18 may be connected to the input potential.

The first comb-shaped electrode 17 includes a first busbar 22 and a plurality of first electrode fingers 25. The plurality of first electrode fingers 25 are connected to the first busbar 22 at their respective one end portions. The second comb-shaped electrode 18 has a second busbar 23 and a plurality of second electrode fingers 26. The plurality of second electrode fingers 26 are connected to the second busbar 23 at their respective one end portions.

The first busbar 22 and the second busbar 23 face each other. In the present example embodiment, the number of the plurality of first electrode fingers 25 and the number of the plurality of second electrode fingers 26 are each, for example, three or more. The plurality of first electrode fingers 25 and the plurality of second electrode fingers 26 are interdigitated with each other.

The direction in which the first electrode fingers 25 and the second electrode fingers 26 extend is hereinafter referred to as an electrode finger extending direction, and a direction orthogonal or substantially orthogonal to the electrode finger extending direction is hereinafter referred to as an electrode finger orthogonal direction. When the direction in which the first electrode fingers 25 and the second electrode fingers 26 face each other is referred to as an electrode finger facing direction, the electrode finger facing direction and the electrode finger orthogonal direction are parallel or substantially parallel.

Between the first comb-shaped electrode 17 and the second comb-shaped electrode 18, a plurality of facing regions F, a plurality of first regions Ga, and a plurality of second regions Gb are provided. FIG. 2 shows a single facing region F, a single first region Ga, and a single second region Gb as an example.

More specifically, a region where the first electrode finger 25 and the second electrode finger 26 adjacent to each other overlap when seen in the electrode finger orthogonal direction is the facing region F. A region between the facing region F and the first busbar 22 is the first region Ga. A region between the facing region F and the second busbar 23 is the second region Gb. The facing regions F, the first regions Ga, and the second regions Gb are regions in the piezoelectric layer 14 that are defined based on the configuration of the functional electrode 11.

The reference potential electrode 19 has a meandering shape. Specifically, the reference potential electrode 19 includes a plurality of third electrode fingers 27 and a plurality of connection electrodes 24. The plurality of third electrode fingers 27 extend in parallel or substantially in parallel to the electrode finger extending direction and are arranged in parallel or substantially in parallel to the electrode finger orthogonal direction. In other words, when a direction in which the plurality of third electrode fingers 27 are arranged in a plan view is referred to as an array direction, the array direction and the electrode finger orthogonal direction are parallel or substantially parallel. A plan view as referred to herein is a view seen from a direction corresponding to the upper side in FIG. 1 along a direction in which the support 13 and the piezoelectric layer 14 are laminated. In FIG. 1, for example, of the support substrate 16 and the piezoelectric layer 14, the piezoelectric layer 14 side is the upper side. Further, a plan view herein is synonymous with a view from a main surface facing direction. The main surface facing direction is a direction in which the first main surface 14a and the second main surface 14b of the piezoelectric layer 14 face each other. More specifically, the main surface facing direction is, for example, a direction normal to the first main surface 14a. In the present example embodiment, when seen from the main surface facing direction, the plurality of third electrode fingers 27 are arranged in the electrode finger orthogonal direction.

In the present example embodiment, the number of the plurality of third electrode fingers 27 is, for example, three or more. One end portions or the other end portions of adjacent third electrode fingers 27 are connected by the connection electrode 24. This makes the shape of the reference potential electrode 19 a meandering shape, for example. The shape of the reference potential electrode 19 is not limited to the meandering shape.

In a plan view, a portion of the reference potential electrode 19 overlaps with a region between the first comb-shaped electrode 17 and the second comb-shaped electrode 18. Specifically, each third electrode finger 27 of the reference potential electrode 19 overlaps with the first region Ga, the facing region F, and the second region Gb in a plan view. Of all of the plurality of connection electrodes 24, some of the plurality of connection electrodes 24 overlap with the first regions Ga in a plan view. These connection electrodes 24 each connect end portions of adjacent third electrode fingers 27 that overlap with the first regions Ga in a plan view.

The rest of the plurality of connection electrodes 24 overlap with the second regions Gb in a plan view. These connection electrodes 24 each connect end portions of adjacent third electrode fingers 27 that overlap with the second regions Gb in a plan view. The connection electrodes 24 provided in the first regions Ga and the connection electrodes 24 provided in the second regions Gb are arranged alternately in the array direction. The reference potential electrode 19 is provided so as to lie in each facing region F, each first region Ga, and each second region Gb.

In a plan view, a portion of the reference potential electrode 19 overlaps with a region outside the first comb-shaped electrode 17 and the second comb-shaped electrode 18. For example, this portion is connected to the reference potential via a different element, such as wiring and an electrode pad. Hereinbelow, the first electrode fingers 25, the second electrode fingers 26, and the third electrode fingers 27 may be referred to simply as electrode fingers.

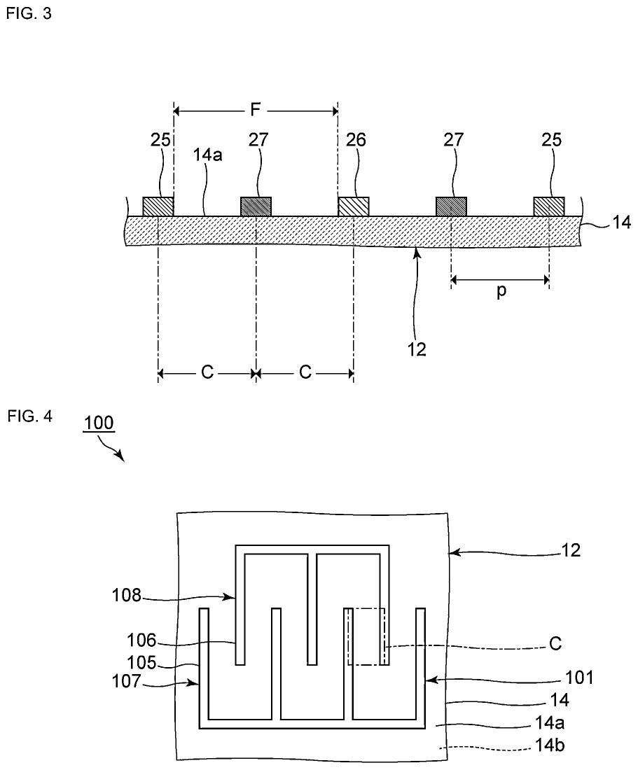

FIG. 3 is a schematic elevational cross-sectional view showing an area around the first to third electrode fingers in the first example embodiment.

The third electrode fingers 27 are provided between adjacent ones of the first electrode fingers 25 and the second electrode fingers 26. The order of arrangement of the first electrode fingers 25, the second electrode fingers 26, and the third electrode fingers 27 is, in a case of starting with the first electrode finger 25, the first electrode finger 25, the third electrode finger 27, the second electrode finger 26, and the third electrode finger 27, which are counted as one period. In other words, the plurality of electrode fingers are arranged so that the potentials of the electrode fingers may be in the following order: the input potential, the reference potential, the output potential, the reference potential, the input potential, and so on. There are at least one first electrode finger 25, at least one second electrode finger 26, and at least one third electrode finger 27.

The first comb-shaped electrode 17, the second comb-shaped electrode 18, and the reference potential electrode 19 all may include a single-layer metal film or a multi-layer metal film.

The acoustic wave device 10 is an acoustic wave resonator configured to be able to use a bulk wave in thickness-shear mode. As shown in FIG. 2, the acoustic wave device 10 has a plurality of excitation regions C. In the plurality of excitation regions C, a bulk wave in thickness-shear mode and an acoustic wave in other mode are excited. FIG. 2 shows only two of the plurality of excitation regions C.

Of all of the excitation regions C, some of the plurality of excitation regions C are a region where the first electrode finger 25 and the third electrode finger 27 adjacent to each other overlap when seen from the electrode finger orthogonal direction, the region being between the centers of the adjacent first electrode finger 25 and third electrode finger 27. The rest of the plurality of excitation regions C are a region where the second electrode finger 26 and the third electrode finger 27 adjacent to each other overlap when seen from the electrode finger orthogonal direction, the region being between the centers of the adjacent second electrode finger 26 and third electrode finger 27. These excitation regions C are arranged in the electrode finger orthogonal direction. The excitation regions C are regions in the piezoelectric layer 14 that are defined based on the configuration of the functional electrode 11.

The present example embodiment includes the following configurations: 1) the first electrode fingers 25, the second electrode fingers 26, and the third electrode fingers 27 are provided on the first main surface 14a of the piezoelectric layer 14, and 2) the third electrode finger 27 overlaps with at least part of at least one facing region F when seen in the main surface facing direction. This makes it possible for the acoustic wave device 10 to obtain favorable filter waveforms. When the acoustic wave device 10 is used in a filter device as an acoustic wave resonator, favorable filter waveforms can be obtained even if the filter device includes a single acoustic wave resonator or a small number of acoustic wave resonators, which enables the filter device to be small in size. Details of this are described below with reference to a comparative example.

As shown in FIG. 4, a comparative example differs from the first example embodiment in not including a reference potential electrode. Specifically, an acoustic wave resonator 100 of the comparative example includes a first comb-shaped electrode 107 and a second comb-shaped electrode 108. An IDT electrode 101 is defined by the first comb-shaped electrode 107 and the second comb-shaped electrode 108. The excitation regions C in the acoustic wave resonator 100 are each a region where a first electrode finger 105 and a second electrode finger 106 adjacent to each other overlap when seen from the electrode finger orthogonal direction, the region being between the centers of the first electrode finger 105 and the second electrode finger 106 adjacent to each other.

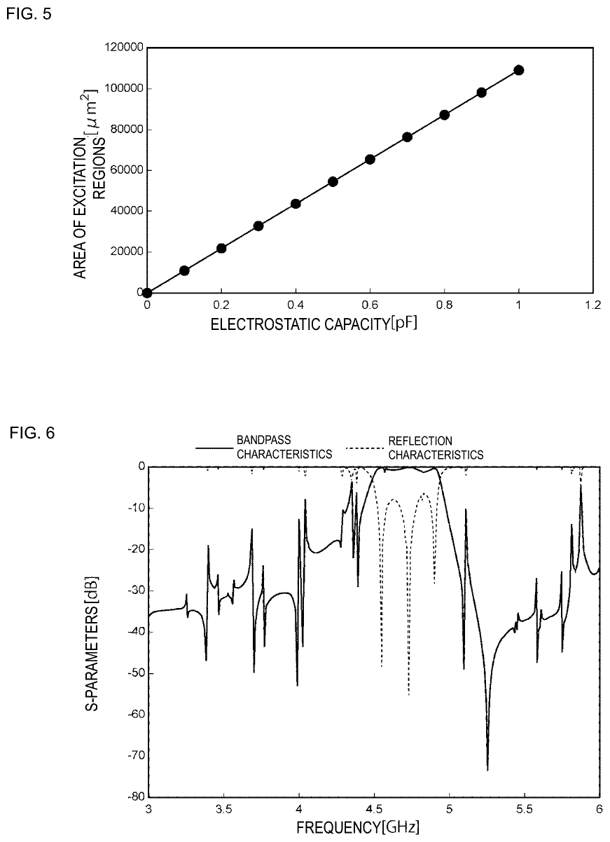

FIG. 5 is a diagram showing an example of the relationship between electrostatic capacitance and the area of the excitation regions in the comparative example. In the example shown in FIG. 5, the thickness of the piezoelectric layer 14 is, for example, about 375 nm, the center-to-center distance between the first electrode finger 105 and the second electrode finger 106 adjacent to each other is, for example, about 4.8 μm, and the width of each electrode finger is, for example, about 960 nm. The width of an electrode finger is a dimension of the electrode finger measured in the electrode finger orthogonal direction.

As shown in FIG. 5, in the comparative example, the larger the electrostatic capacitance of the acoustic wave resonator 100, the larger the area of the excitation regions C. In a case where the acoustic wave resonator 100 is used in a filter device, in order to obtain favorable filter waveforms, the capacitance ratio between a plurality of acoustic wave resonators 100 needs to be increased. However, using an acoustic wave resonator 100 with a large electrostatic capacitance makes it difficult for the filter device to be small in size.

In contrast, in the first example embodiment shown in FIG. 1, favorable filter waveforms can be obtained with the acoustic wave device 10. Thus, when the acoustic wave device 10 is used in a filter device as an acoustic wave resonator, favorable filter waveforms can be obtained even if the filter device includes a single acoustic wave resonator or a small number of acoustic wave resonators, which enables the filter device to be smaller in size. The bandpass characteristics and reflection characteristics of the acoustic wave device 10 as an acoustic wave resonator are shown below.

FIG. 6 is a diagram showing the bandpass characteristics and reflection characteristics of the acoustic wave device according to the first example embodiment. FIG. 6 shows results of FEM (Finite Element Method) simulation.

As shown in FIG. 6, favorable filter waveforms can be obtained even with a single acoustic wave device 10. The acoustic wave device 10 is an acoustic-coupling filter. More specifically, as shown in FIG. 3, the acoustic wave device 10 includes the excitation region C located between the centers of the first electrode finger 25 and the third electrode finger 27 adjacent to each other and the excitation region C located between the centers of the second electrode finger 26 and the third electrode finger 27 adjacent to each other. In these excitation regions C, acoustic waves in a plurality of modes including a bulk wave in thickness-shear mode are excited. Coupling these modes enables favorable filter waveforms to be obtained even with a single acoustic wave device 10.

The configuration of the first example embodiment is described in more detail below.

As shown in FIG. 1, the support 13 includes the support substrate 16 and the insulating layer 15. The piezoelectric substrate 12 is a multilayer body including the support substrate 16, the insulating layer 15, and the piezoelectric layer 14. Thus, the piezoelectric layer 14 and the support 13 overlap when seen from the main surface facing direction. Examples of a material usable for the support substrate 16 include, for example, semiconductors such as silicon and ceramics such as aluminum oxide. An appropriate dielectric, for example, such as silicon oxide or tantalum oxide, can be used as a material for the insulating layer 15. The piezoelectric layer 14 is, for example, a lithium niobate layer such as a LiNbO₃ layer or a lithium tantalate layer such as a LiTaO₃ layer.

The insulating layer 15 is provided with a cavity portion 10a. More specifically, a recess is provided in the insulating layer 15. The piezoelectric layer 14 is provided on the insulating layer 15, closing the recess. Thus, a hollow portion is provided. This hollow portion is the cavity portion 10a. In the present example embodiment, the support 13 and the piezoelectric layer 14 are disposed such that a portion of the support 13 and a portion of the piezoelectric layer 14 face each other with the cavity portion 10a interposed in between. The recess in the support 13 may be provided to extend in both the insulating layer 15 and the support substrate 16. Alternatively, the recess may be provided only in the support substrate 16 and closed by the insulating layer 15. The recess may be provided in the piezoelectric layer 14. Note that the cavity portion 10a may be a through-hole provided in the support 13.

The cavity portion 10a is an acoustic reflection portion. The acoustic reflection portion can effectively trap the energy of an acoustic wave at the piezoelectric layer 14 side. The acoustic reflection portion is located at such a location on the support 13 as to overlap with at least a portion of the functional electrode 11 in a plan view. More specifically, at least a portion of each of the first electrode fingers 25 and the second electrode fingers 26 overlaps with the cavity portion 10a in a plan view. It is preferable that at least a portion of each of the first electrode fingers 25, the second electrode fingers 26, and the third electrode fingers 27 overlap with the cavity portion 10a in a plan view. It is more preferable that the plurality of excitation regions C overlap with the cavity portion 10a in a plan view. As described earlier, a plan view as referred to herein is synonymous with a view from the main surface facing direction.

In the first example embodiment, the first electrode fingers 25, the second electrode fingers 26, and the third electrode finger 27 are provided on the same main surface of the piezoelectric layer 14. For example, the first electrode fingers 25 and the second electrode fingers 26 may be provided on the first main surface 14a, and the third electrode fingers 27 may be provided on the second main surface 14b. Alternatively, the first electrode fingers 25 and the second electrode fingers 26 may be provided on the second main surface 14b, and the third electrode fingers 27 may be provided on the first main surface 14a.

In these cases as well, the third electrode fingers 27 overlap with at least a portion of the facing regions F shown in FIG. 2 in a plan view. In these cases, the first electrode finger 25 and the third electrode finger 27 adjacent to each other are the first electrode finger 25 and the third electrode finger 27 adjacent to each other in a plan view. Similarly, the second electrode finger 26 and the third electrode finger 27 adjacent to each other are the second electrode finger 26 and the third electrode finger 27 adjacent to each other in a plan view. This applies to a case where the first electrode fingers 25, the second electrode fingers 26, and the third electrode finger 27 are provided on the same main surface. Electrode fingers adjacent to each other in a plan view are synonymous with electrode fingers adjacent to each other when seen from the main surface facing direction.

In the first example embodiment, the center-to-center distances of the plurality of pairs of the first electrode finger 25 and the third electrode finger 27 adjacent to each other in a plan view and the center-to-center distances of the plurality of pairs of the second electrode finger 26 and the third electrode finger 27 adjacent to each other in a plan view are the same or substantially the same. In this case, it is preferable that d/p is, for example, about 0.5 or below, where d is the thickness of the piezoelectric layer 14 and p is the center-to-center distance between adjacent electrode fingers. More preferably, d/p is, for example, about 0.24 or below. This enables a bulk wave in thickness-shear mode to be excited favorably.

The center-to-center distance between the first electrode finger 25 and the third electrode finger 27 adjacent to each other in a plan view and the center-to-center distance between the second electrode finger 26 and the third electrode finger 27 adjacent to each other in a plan view do not have to be constant. In this case, p is preferably the longest one of the center-to-center distances between the first electrode fingers 25 and the third electrode fingers 27 adjacent to each other in a plan view and the center-to-center distances between the second electrode fingers 26 and the third electrode fingers 27 adjacent to each other in a plan view. In this case, d/p is, for example, preferably about 0.5 or below or more preferably about 0.24 or below. The acoustic wave devices of example embodiments of the present invention do not necessarily have to be configured to be able to use thickness-shear mode.

In the first example embodiment, the frequency and the bandwidth can be adjusted through adjustment of the center-to-center distance p of adjacent electrode fingers. This example is shown below. Specifically, bandpass characteristics were found through FEM simulation with various values of the center-to-center distance p. Design parameters for the acoustic wave device 10 are as follows.

The piezoelectric layer:
material . . . Z-cut LiNbO₃
thickness . . . about 400 nm

The first to third electrode fingers:
material . . . Al
thickness . . . about 500 nm
width . . . about 800 nm

The center-to-center distance p:
About 4 μm or about 2 μm

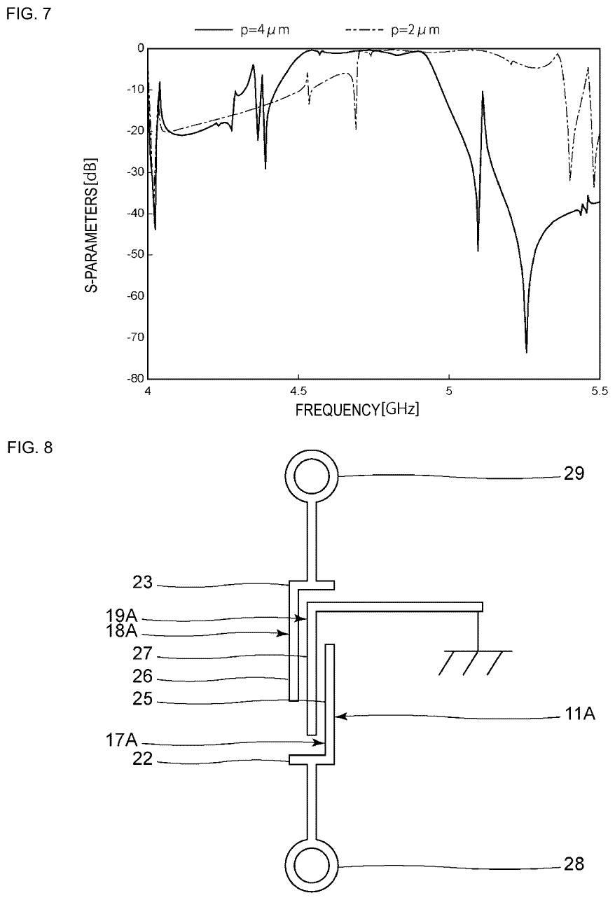

FIG. 7 is a diagram showing the relationship between the center-to-center distance between adjacent electrode fingers and the bandpass characteristics in the first example embodiment.

As shown in FIG. 7, when the center-to-center distance p between adjacent electrode fingers is varied, the position of the pass band and the width of the band change. Thus, adjusting the center-to-center distance p makes it possible to obtain bandpass characteristics with a desired pass band position and a desired bandwidth.

In the acoustic wave device 10, a plurality of modes including a bulk wave in thickness-shear mode are excited. The pass band is defined by the frequency interval between modes different from each other. Then, adjusting the center-to-center distance p between adjacent electrode fingers makes it possible to adjust the position of each mode and the frequency interval between modes different from each other. This enables adjustment of the position of the pass band and the width of the band.

An example embodiment of the present invention is provided with at least one first electrode finger 25, at least one second electrode finger 26, and at least one third electrode finger 27. The first comb-shaped electrode 17 and the second comb-shaped electrode 18 do not necessarily have to be provided.

The acoustic wave device 10 preferably includes a plurality of facing regions F. In this case, at least one of the first electrode finger 25 and the second electrode finger 26 includes a plurality of electrode fingers. The plurality of facing regions F may thus be provided. More preferably, both of the first electrode finger 25 and the second electrode finger 26 include a plurality of electrode fingers.

In an example embodiment of the present invention, at least one third electrode finger 27 is provided on at least one of the first main surface 14a and the second main surface 14b of the piezoelectric layer 14. Then, the at least one third electrode finger 27 overlaps with at least a portion of at least one facing region F in a plan view.

However, it is preferable that the third electrode finger 27 includes a plurality of electrode fingers and that the plurality of third electrode fingers 27 are arranged as in the first example embodiment. Specifically, it is preferable that in a plan view, at least two third electrode fingers 27 arranged consecutively in the array direction overlap with respective facing regions F arranged consecutively in the electrode finger orthogonal direction among the plurality of facing regions F. It is more preferable that in a plan view, three or more third electrode fingers 27 arranged consecutively in the array direction overlap with respective facing regions F arranged consecutively in the electrode finger orthogonal direction among the plurality of facing regions F. This enables the acoustic wave device 10 to obtain filter waveforms more surely. The array direction is preferably parallel or substantially parallel to the electrode finger orthogonal direction.

In an example embodiment of the present invention, at least one third electrode finger 27 is provided. For example, in a modification of the first example embodiment shown in FIG. 8, a reference potential electrode 19A includes a single third electrode finger 27. The reference potential electrode 19A does not include a connection electrode. The reference potential electrode 19A includes wiring connected to the reference potential, similarly to the first example embodiment. This wiring connects the third electrode finger 27 to the reference potential.

In the present modification, a functional electrode 11A includes a pair of the first electrode finger 25 and the second electrode finger 26. In other words, a first comb-shaped electrode 17A includes one first electrode finger 25. Similarly, a second comb-shaped electrode 18A includes one second electrode finger 26. In a case where the acoustic wave device of the present modification is used as an acoustic wave resonator in a filter device, similarly to the first example embodiment, favorable filter waveforms can be obtained even if the filter device is formed by a single acoustic wave resonator or a small number of acoustic wave resonators. Thus, the filter device can be reduced in size.

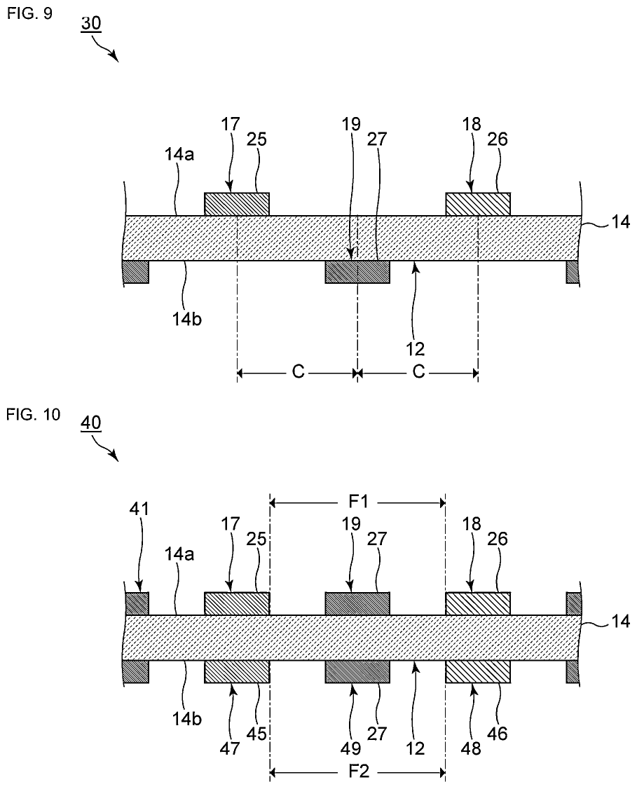

FIG. 9 is a schematic elevational cross-sectional view showing an area around the first to third electrode fingers in a second example embodiment of the present invention.

The present example embodiment differs from the first example embodiment in that the reference potential electrode 19 is provided on the second main surface 14b of the piezoelectric layer 14. Except for the above point, an acoustic wave device 30 of the present example embodiment has a configuration the same as or similar to that of the acoustic wave device 10 of the first example embodiment.

In the present example embodiment, a region where the first electrode finger 25 and the third electrode finger 27 adjacent to each other overlap in the electrode finger orthogonal direction in a plan view is the excitation region C, the region being between the centers of the first electrode finger 25 and the third electrode finger 27 adjacent to each other. A region where the second electrode finger 26 and the third electrode finger 27 adjacent to each other overlap in the electrode finger orthogonal direction in a plan view is also the excitation region C, the region being between the centers of the second electrode finger 26 and the third electrode finger 27 adjacent to each other. In other words, the excitation region C is a region where the first electrode finger 25 and the second electrode finger 26 adjacent to each other directly or with the third electrode finger 27 interposed in between when seen in the main surface facing direction overlap in the electrode finger orthogonal direction.

Similarly to the first example embodiment, favorable filter waveforms of the acoustic wave device 30 can be obtained. Thus, when the acoustic wave device 30 as an acoustic wave resonator is used in a filter device, the filter device can be provided with a fewer number of acoustic wave resonators. Thus, the filter device can be reduced in size.

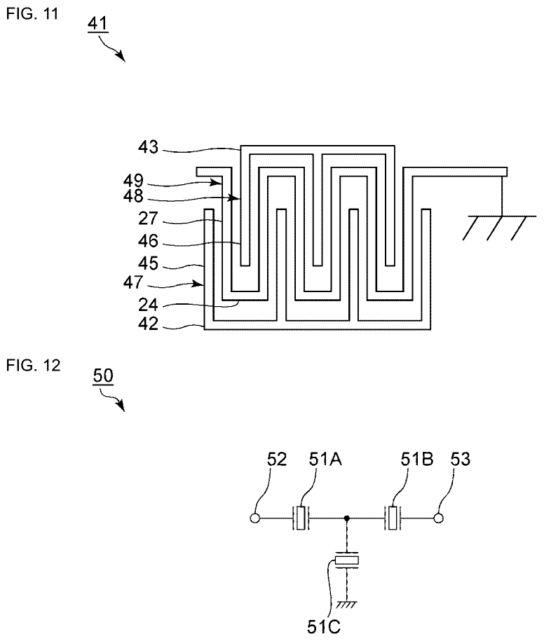

FIG. 10 is a schematic elevational cross-sectional view showing an area around first to fifth electrode fingers in a third example embodiment of the present invention. FIG. 11 is a schematic bottom view showing an electrode structure on the second main surface of the piezoelectric layer in the third example embodiment.

As shown in FIG. 10, the present example embodiment differs from the first example embodiment in that a pair of comb-shaped electrodes and a reference potential electrode are provided on both of the main surfaces of the piezoelectric layer 14. A functional electrode 41 includes the first comb-shaped electrode 17, the second comb-shaped electrode 18, the reference potential electrode 19, a fourth comb-shaped electrode 47, a fifth comb-shaped electrode 48, and a reference potential electrode 49. The fourth comb-shaped electrode 47 is actually the third comb-shaped electrode in the functional electrode 41 but is referred to as the fourth comb-shaped electrode 47 for convenience. Except for the above point, an acoustic wave device 40 of the present example embodiment has a configuration the same as or similar to that of the acoustic wave device 10 of the first example embodiment.

The first comb-shaped electrode 17, the second comb-shaped electrode 18, and the reference potential electrode 19 are provided on the first main surface 14a of the piezoelectric layer 14. The functional electrode 41 on the first main surface 14a has a configuration the same as or similar to that in the first example embodiment. Meanwhile, the fourth comb-shaped electrode 47, the fifth comb-shaped electrode 48, and the reference potential electrode 49 are provided on the second main surface 14b.

As shown in FIG. 11, the fourth comb-shaped electrode 47 includes a fourth busbar 42 and a plurality of fourth electrode fingers 45. The plurality of fourth electrode fingers 45 are connected to the fourth busbar 42 at their respective one end portions. The fifth comb-shaped electrode 48 includes a fifth busbar 43 and a plurality of fifth electrode fingers 46. The plurality of fifth electrode fingers 46 are connected to the fifth busbar 43 at their respective one end portions.

The fourth busbar 42 and the fifth busbar 43 face each other. In the present example embodiment, there are three or more fourth electrode fingers 45 and three or more fifth electrode fingers 46. The plurality of fourth electrode fingers 45 and the plurality of fifth electrode fingers 46 are interdigitated with each other. The fourth comb-shaped electrode 47 is connected to the input potential. Meanwhile, the fifth comb-shaped electrode 48 is connected to the output potential.

In the present example embodiment, the fourth busbar 42 shown in FIG. 11 and the first busbar 22 shown using FIG. 1 are electrically connected. For example, the fourth busbar 42 and the first busbar 22 may be connected by a penetrating electrode penetrating through the piezoelectric layer 14.

Similarly, the fifth busbar 43 shown in FIG. 11 and the second busbar 23 shown using FIG. 1 are electrically connected. For example, the fifth busbar 43 and the second busbar 23 may be connected by a penetrating electrode penetrating through the piezoelectric layer 14.

The reference potential electrode 19 provided on the first main surface 14a of the piezoelectric layer 14 and the reference potential electrode 49 provided on the second main surface 14b shown in FIG. 10 are provided in the same or similar manner. Specifically, the reference potential electrode 49 shown in FIG. 11 includes a plurality of third electrode fingers 27 and a plurality of connection electrodes 24. One end portions or the other end portions of adjacent third electrode fingers 27 are connected to each other by the connection electrode 24. This makes the shape of the reference potential electrode 49 a meandering shape. A portion of the reference potential electrode 49 overlaps with a region between the fourth comb-shaped electrode 47 and the fifth comb-shaped electrode 48 in a plan view. There are at least one fourth electrode finger 45, at least one fifth electrode finger 46, and at least one third electrode finger 27 in the reference potential electrode 49.

As shown in FIG. 10, the fourth electrode finger 45 faces the first electrode finger 25 with the piezoelectric layer 14 interposed in between. The fifth electrode finger 46 faces the second electrode finger 26 with the piezoelectric layer 14 interposed in between. The third electrode finger 27 provided on the second main surface 14b of the piezoelectric layer 14 overlaps with the third electrode finger 27 provided on the first main surface 14a with the piezoelectric layer 14 interposed in between.

In the present example embodiment, the center-to-center distance between the fourth electrode finger 45 and the third electrode finger 27 adjacent to each other in a plan view is the same or substantially the same as the center-to-center distance between the first electrode finger 25 and the third electrode finger 27 adjacent to each other in a plan view. The center-to-center distance between the fifth electrode finger 46 and the third electrode finger 27 adjacent to each other in a plan view is the same or substantially the same as the center-to-center distance between the second electrode finger 26 and the third electrode finger 27 adjacent to each other in a plan view.

A region where the first electrode finger 25 and the second electrode finger 26 adjacent to each other overlap when seen from the electrode finger orthogonal direction is a first facing region F1. The first facing region F1 corresponds to the facing region F in the first example embodiment shown in FIG. 2. A region where the fourth electrode finger 45 and the fifth electrode finger 46 adjacent to each other overlap when seen from the electrode finger orthogonal direction is a second facing region F2. The first facing region F1 is a region in the first main surface 14a of the piezoelectric layer 14 defined based on the configuration of the functional electrode 41. The second facing region F2 is a region in the second main surface 14b of the piezoelectric layer 14 defined based on the configuration of the functional electrode 41.

The first facing region F1 and the second facing region F2 overlap in a plan view. Then, each of the third electrode fingers 27 provided on the first main surface 14a and the second main surface 14b of the piezoelectric layer 14 overlap with the first facing region F1 and the second facing region F2 in a plan view.

Similarly to the first example embodiment, favorable filter waveforms can be obtained with the acoustic wave device 40. Thus, in a case where the acoustic wave device 40 is used as an acoustic wave resonator in a filter device, favorable filter waveforms can be obtained even if the filter device includes a single acoustic wave resonator or a small number of acoustic wave resonators, which enables the filter device to be small in size.

As shown in FIG. 10, in the present example embodiment, the plurality of third electrode fingers 27 are provided on both the first main surface 14a and the second main surface 14b of the piezoelectric layer 14, arranged consecutively in the array direction. Then, the third electrode fingers 27 provided on the first main surface 14a and the third electrode fingers 27 provided on the second main surface 14b overlap in a plan view. Thus, a given third electrode finger 27 provided on the first main surface 14a and a third electrode finger 27 adjacent thereto in a plan view are the third electrode finger 27 provided on the first main surface 14a and the third electrode finger 27 provided on the second main surface 14b.

The third electrode fingers 27 overlapping in a plan view are not arranged in the array direction. Meanwhile, the third electrode fingers 27 not overlapping in a plan view are arranged in the array direction. The present example embodiment holds true even when, for example, three third electrode fingers 27 arranged consecutively in the array direction are three third electrode fingers 27 provided on the first main surface 14a. Alternatively, the present example embodiment holds true even when, for example, the above-described three third electrode fingers 27 are two third electrode fingers 27 provided on the first main surface 14a and a single third electrode finger 27 provided on the second main surface 14b. In this way, the third electrode fingers 27 arranged consecutively in the array direction may include the third electrode finger 27 provided on the first main surface 14a or may include the third electrode finger 27 provided on the second main surface 14b.

For example, the plurality of third electrode fingers 27 may be provided so as to be arranged in the array direction alternately on the first main surface 14a and the second main surface 14b of the piezoelectric layer 14. In this case, a given third electrode finger 27 provided on the first main surface 14a and a third electrode finger 27 adjacent thereto in a plan view are the third electrode fingers 27 provided on the second main surface 14b.

In this case, the third electrode fingers 27 arranged consecutively in the array direction include both the third electrode finger 27 provided on the first main surface 14a of the piezoelectric layer 14 and the third electrode finger 27 provided on the second main surface 14b.

It is also preferable in this case that in a plan view, at least two third electrode fingers 27 arranged consecutively in the array direction overlap with respective facing regions F arranged consecutively in the electrode finger orthogonal direction among the plurality of facing regions F. It is more preferable that in a plan view, three or more third electrode fingers 27 arranged consecutively in the array direction overlap with respective facing regions F arranged consecutively in the electrode finger orthogonal direction among the plurality of facing regions F. This enables filter waveforms to be obtained more reliably.

FIG. 12 is a circuit diagram of an acoustic wave filter device according to a fourth example embodiment of the present invention.

An acoustic wave filter device 50 includes a first signal terminal 52, a second signal terminal 53, an acoustic wave resonator 51A, an acoustic wave resonator 51B, and an acoustic wave resonator 51C. The acoustic wave resonator 51A is an acoustic wave device according to an example embodiment of the present invention. The acoustic wave resonator 51A may have, for example, any of the configurations of the first to third example embodiments and the modification of the first example embodiment. Meanwhile, the functional electrodes in the acoustic wave resonator 51B and the acoustic wave resonator 51C are each an IDT electrode.

For example, the first signal terminal 52 and the second signal terminal 53 may be configured as electrode pads or may be configured as wiring. In the present example embodiment, the second signal terminal 53 is an antenna terminal. The antenna terminal is connected to an antenna.

The acoustic wave resonator 51A and the acoustic wave resonator 51B are series-connected to each other between the first signal terminal 52 and the second signal terminal 53. The acoustic wave resonator 51C is connected between a reference potential and a connection point between the acoustic wave resonator 51A and the acoustic wave resonator 51B.

In the acoustic wave filter device 50, the acoustic wave device according to an example embodiment of the present invention is used as the acoustic wave resonator 51A. Thus, favorable filter waveforms can be obtained without a size increase in the acoustic wave filter device 50. Therefore, the acoustic wave filter device 50 can be reduced in size.

The circuit configuration of the acoustic wave filter device 50 is not limited to the one described above. For example, the acoustic wave filter device 50 may include only the acoustic wave resonator 51A, which is the acoustic wave device according to an example embodiment of the present invention.

Using an example where the functional electrode is an IDT electrode, the following describes details of thickness-shear mode. The IDT electrode includes no third electrode fingers. “Electrodes” in the IDT electrode described below correspond to electrode fingers. A support in the following example corresponds to the support substrate. Hereinbelow, the reference potential may be described as a ground potential.

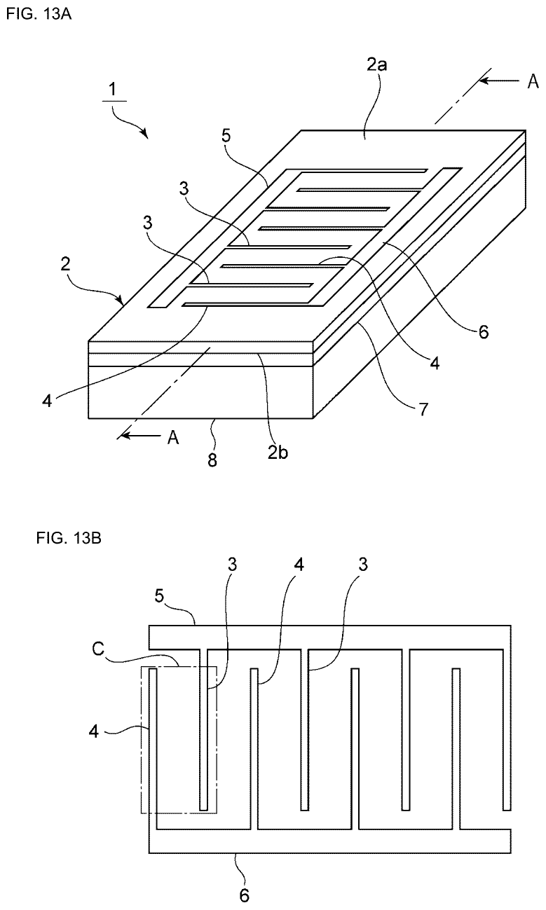

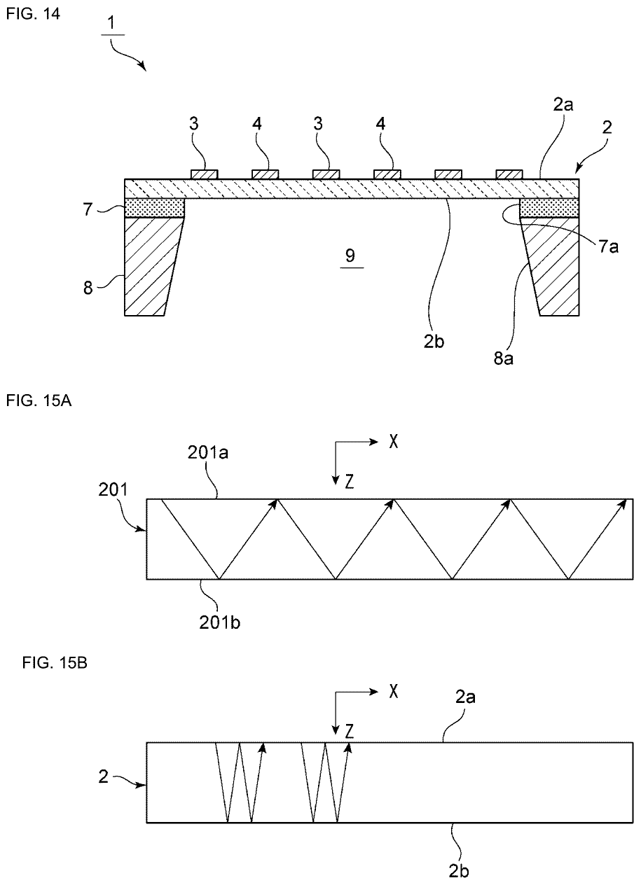

FIG. 13A is a schematic perspective view showing the external appearance of an acoustic wave device that uses a bulk wave in thickness-shear mode, FIG. 13B is a plan view showing an electrode structure on the piezoelectric layer, and FIG. 14 is a sectional view taken along the line A-A in FIG. 13A.

An acoustic wave device 1 includes a piezoelectric layer 2 made of LiNbO₃, for example. The piezoelectric layer 2 may be made of LiTaO₃, for example. The cut-angle of LiNbO₃ or LiTaO₃ is Z-cut, but may be rotated Y-cut or X-cut. Although not limited to a particular value, the thickness of the piezoelectric layer 2 is, for example, preferably about 40 nm or greater and about 1000 nm or below and is more preferably about 50 nm or greater and about 1000 nm or below in order for thickness-shear mode to be effectively excited. The piezoelectric layer 2 includes first and second main surfaces 2a and 2b facing each other. Electrodes 3 and electrodes 4 are provided on the first main surface 2a. Here, the electrodes 3 are an example of a “first electrode,” and the electrodes 4 are an example of a “second electrode”. In FIGS. 13A and 13B, the plurality of electrodes 3 are connected to a first busbar 5. The plurality of electrodes 4 are connected to a second busbar 6. The plurality of electrodes 3 and the plurality of electrodes 4 are interdigitated with each other. The electrodes 3 and the electrodes 4 have a rectangular or substantially rectangular shape and has a length direction. The electrode 3 and the electrode 4 next thereto face each other in the direction orthogonal to the length direction. The length direction of the electrodes 3 and 4 and the direction orthogonal or substantially orthogonal to the length direction of the electrodes 3 and 4 are both a direction intersecting with the thickness direction of the piezoelectric layer 2. Thus, it can also be said that the electrode 3 and the electrode 4 next thereto face each other in a direction intersecting with the thickness direction of the piezoelectric layer 2. Also, the length direction of the electrodes 3 and 4 may be switched with the direction orthogonal or substantially orthogonal to the length direction of the electrodes 3 and 4 shown in FIGS. 13A and 13B. In other words, in FIGS. 13A and 13B, the electrodes 3 and 4 may extend in the direction in which the first busbar 5 and the second busbar 6 extend. In this case, the first busbar 5 and the second busbar 6 extend in the direction in which the electrodes 3 and 4 extend in FIGS. 13A and 13B. Then, a plurality of structures each being a pair of the electrode 3 connected to one potential and the electrode 4 adjacent thereto and connected to the other potential that are adjacent to each other are provided in the direction orthogonal or substantially orthogonal to the length direction of the electrodes 3 and 4. Here, the electrode 3 and the electrode 4 being adjacent to each other refers not to a case where the electrode 3 and the electrode 4 are disposed to be in direct contact, but to a case where the electrode 3 and the electrode 4 are disposed with a gap interposed in between. Also, in a case where the electrode 3 and the electrode 4 are adjacent to each other, an electrode connected to a hot electrode or a ground electrode, including other electrodes 3 and 4, is not disposed between the electrode 3 and the electrode 4. The number of these pairs does not need to be an integer, and there may be 1.5 pairs, 2.5 pairs, or the like. The center-to-center distance, i.e., the pitch, between the electrodes 3 and 4 is, for example, preferably in the range of about 1 μm or greater and about 10 μm or below. Also, the width of the electrodes 3 and 4, i.e., the dimension of the electrodes 3 and 4 measured in the facing direction, is, for example, preferably in the range of about 50 nm or greater and about 1000 nm or below and more preferably in the range of about 150 nm or greater and about 1000 nm or below. The center-to-center distance between the electrodes 3 and 4 is the distance of a line connecting the center of the dimension (the width dimension) of the electrode 3 measured in the direction orthogonal or substantially orthogonal to the length direction of the electrode 3 and the center of the dimension (the width dimension) of the electrode 4 measured in the direction orthogonal or substantially orthogonal to the length direction of the electrode 4.

Also, because the Z-cut piezoelectric layer is used in the acoustic wave device 1, the direction orthogonal or substantially orthogonal to the length direction of the electrodes 3 and 4 is a direction orthogonal or substantially orthogonal to the polarization direction of the piezoelectric layer 2, unless a piezoelectric body with a different cut-angle is used as the piezoelectric layer 2. As referred to herein, being “orthogonal” is not limited only to being strictly orthogonal, and includes being substantially orthogonal (an angle formed between the polarization direction and a direction orthogonal to the length direction of the electrodes 3 and 4 is in the range of, for example, about 90°±10°.

A support 8 is laminated at the second main surface 2b side of the piezoelectric layer 2 with an insulating layer 7 interposed in between. The insulating layer 7 and the support 8 are frame-shaped and, as shown in FIG. 14, include through-holes 7a, 8a. A cavity portion 9 is thus provided. The cavity portion 9 is provided not to inhibit vibration of the excitation regions C in the piezoelectric layer 2. Thus, the support 8 is laminated on the second main surface 2b with the insulating layer 7 interposed in between, at a location not overlapping with the portion where at least a pair of electrodes 3 and 4 is provided. The insulating layer 7 does not have to be provided. Thus, the support 8 may be laminated on the second main surface 2b of the piezoelectric layer 2 either directly or indirectly.

The insulating layer 7 is made of silicon oxide, for example. Besides silicon oxide, any appropriate insulating material can be used such as silicon oxynitride or alumina, for example. The support 8 is made of Si, for example. The plane orientation of Si at the surface on the piezoelectric layer 2 side may be (100) or (110) or may be (111). Si of the support 8 is preferably of high resistance, having a resistivity of, for example, about 4 kΩcm or greater. The support 8 also can be made using an appropriate insulating or semiconductor material.

Examples of a material usable for the support 8 include aluminum oxide, piezoelectric materials such as lithium tantalate, lithium niobate, and quartz crystal, various ceramics such as alumina, magnesia, sapphire, silicon nitride, aluminum nitride, silicon carbide, zirconia, cordierite, mullite, steatite, and forsterite, dielectrics such as diamond and glass, and semiconductors such as gallium nitride.

The plurality of electrodes 3 and 4 and the first and second busbars 5 and 6 described above are made of an appropriate metal or alloy, such as Al or an AlCu alloy, for example. In the acoustic wave device 1, the electrodes 3 and 4 and the first and second busbars 5 and 6 have a structure, for example, in which an Al film is laminated on a Ti film. An adhesion layer other than a Ti film may be used.

For driving, an AC voltage is applied between the plurality of electrodes 3 and the plurality of electrodes 4. More specifically, an AC voltage is applied between the first busbar 5 and the second busbar 6. This enables resonance characteristics to be obtained using a bulk wave in thickness-shear mode which is excited in the piezoelectric layer 2. Also, in the acoustic wave device 1, d/p is, for example, about 0.5 or below where d is the thickness of the piezoelectric layer 2 and p is the center-to-center distance of any of the plurality of pairs of the electrodes 3 and 4 adjacent to each other. Thus, the above-described bulk wave in thickness-shear mode is excited effectively, enabling favorable resonance characteristics to be obtained. More preferably, d/p is, for example, about 0.24 or below, and in this case, even more favorable resonance characteristics can be obtained.

In the acoustic wave device 1 having the above-described configuration, even if the number of pairs of the electrodes 3 and 4 is decreased with an attempt to reduce the size, the Q factor does not decrease easily. This is because propagation loss is small even if reflectors at both sides have fewer electrode fingers. Also, the number of electrode fingers can be reduced because of the use of a bulk wave in thickness-shear mode. The difference between a Lamb wave used in an acoustic wave device and a bulk wave in thickness shear mode described above is described with reference to FIGS. 15A and 15B.

FIG. 15A is a schematic elevational cross-sectional view illustrating a Lamp wave propagating in a piezoelectric film in an acoustic wave device like the one described in Japanese Unexamined Patent Application Publication No. 2012-257019. A wave propagates in a piezoelectric film 201 as indicated by the arrows. In the piezoelectric film 201, a first main surface 201a and a second main surface 201b face each other, and the thickness direction connecting the first main surface 201a and the second main surface 201b is the Z-direction. The X-direction is a direction in which the electrode fingers of an IDT electrode are arranged. As shown in FIG. 15A, a Lamb wave propagates in the X-direction as indicated. A Lamb wave is a plate wave and therefore makes the whole piezoelectric film 201 vibrate, but because the wave propagates in the X-direction, reflectors are disposed at both sides to obtain resonance characteristics. Thus, wave propagation loss occurs, and the Q factor decreases when an attempt is made to reduce the size, i.e., the number of pairs of electrode fingers is decreased.

In contrast, as shown in FIG. 15B, in the acoustic wave device 1 in which vibrational displacement is in the thickness-shear direction, the wave propagates almost in a direction connecting the first main surface 2a and the second main surface 2b of the piezoelectric layer 2, i.e., the Z-direction, and resonates. In other words, the X-direction component of the wave is significantly smaller than the Z-direction component. Because such wave propagation in the Z-direction enables resonance characteristics to be obtained, propagation loss does not occur easily even if there are a fewer number of electrode fingers of the reflectors. Further, the Q factor does not decrease easily even when the number of electrode pairs formed by the electrodes 3 and 4 is decreased to aim for a smaller size.

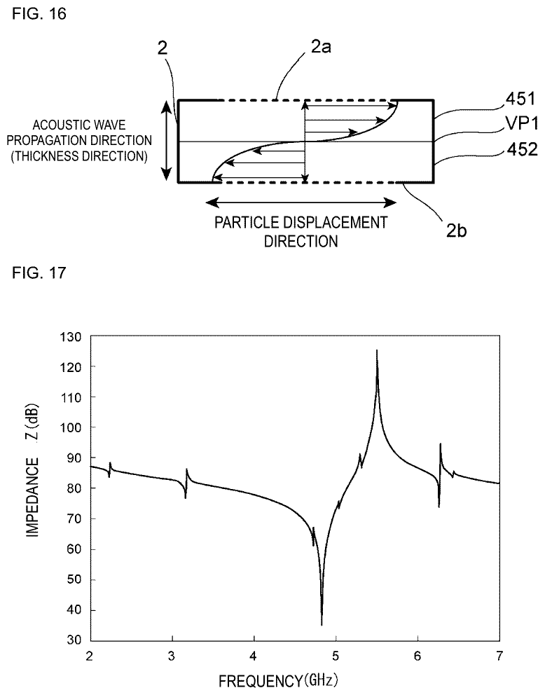

The amplitude direction of a bulk wave in thickness-shear mode is, as shown in FIG. 16, opposite between a first region 451 included in the excitation region C in the piezoelectric layer 2 and a second region 452 included in the excitation region C. FIG. 16 schematically shows a bulk wave in a case where a voltage is applied between the electrode 3 and the electrode 4, the voltage making the electrode 4 at a higher potential than the electrode 3. The first region 451 is a region in the excitation region C between the first main surface 2a and a virtual plane VP1 which is orthogonal or substantially orthogonal to the thickness direction of the piezoelectric layer 2 and halves the piezoelectric layer 2. The second region 452 is a region in the excitation region C between the second main surface 2b and the virtual plane VP1.

As described above, at least one electrode pair including the electrode 3 and the electrode 4 is disposed in the acoustic wave device 1, but because the wave does not propagate in the X-direction, the number of electrode pairs of the electrodes 3 and 4 does not need to be more than one. In other words, at least one pair of electrodes is provided.

For example, the electrode 3 is an electrode connected to the hot potential, and the electrode 4 is an electrode connected to the ground potential. The electrode 3 may be connected to the ground potential, and the electrode 4 may be connected to the hot potential. In the acoustic wave device 1, at least one pair of electrodes are, as described above, an electrode connected to the hot potential and an electrode connected to the ground potential, and there is no floating electrode.

FIG. 17 is a diagram showing the resonance characteristics of the acoustic wave device shown in FIG. 14. Note that design parameters for the acoustic wave device 1 with which the resonance characteristics are obtained are as follows.

The piezoelectric layer 2: LiNbO₃ with the Euler angles (0°, 0°, 90°), thickness=about 400 nm

The length of a region where the electrode 3 and the electrode 4 overlap when seen in a direction orthogonal or substantially orthogonal to the length direction of the electrode 3 and the electrode 4, i.e., the length of the excitation region C=about 40 μm, the number of electrode pairs formed by the electrodes 3 and 4=21 pairs, the center-to-center distance between the electrodes=about 3 μm, the width of the electrodes 3 and 4=about 500 nm, d/p=about 0.133

The insulating layer 7: a silicon oxide film with a thickness of about 1 μm

The support 8: Si

The length of the excitation region C is a dimension of the excitation region C measured in the length direction of the electrodes 3 and 4.

In the acoustic wave device 1, all of the plurality of electrode pairs including the electrodes 3 and 4 have the same or substantially the same electrode-to-electrode distance. In other words, the electrodes 3 and the electrodes 4 are disposed at an equal or substantially equal pitch.

As is apparent from FIG. 17, even though the acoustic wave device 1 does not include any reflectors, favorable resonance characteristics with a fractional bandwidth of about 12.5% are obtained.

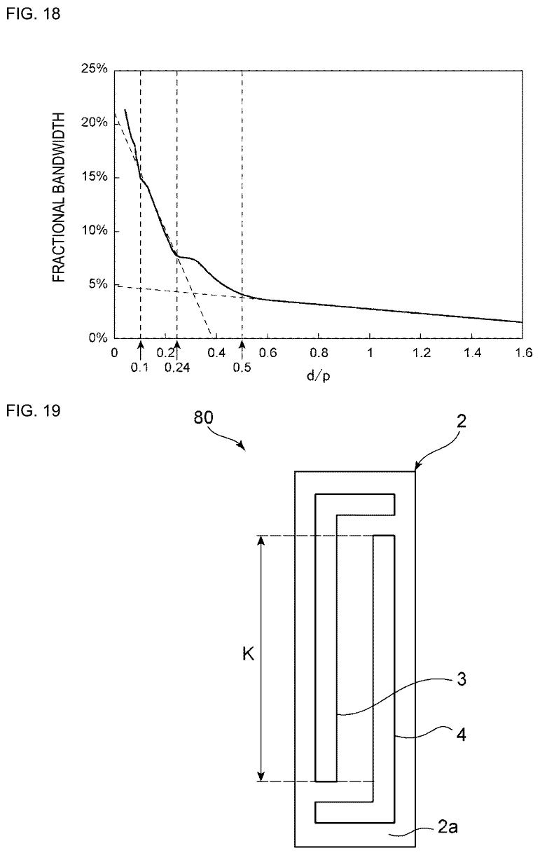

In the acoustic wave device 1, d/p is, for example, as described above, about 0.5 or below or more preferably about 0.24 or below, where d is the thickness of the piezoelectric layer 2 and p is the center-to-center distance between the electrode 3 and the electrode 4. This is described with reference to FIG. 18.

A plurality of acoustic wave devices were obtained, which were the same as or similar to the acoustic wave device with which the resonance characteristics shown in FIG. 17 are obtained but with different values of d/p. FIG. 18 is a diagram showing the relationship between d/p and the fractional bandwidth of each acoustic wave device as a resonator.

As is apparent from FIG. 18, when d/p>about 0.5, the fractional bandwidth is less than about 5% despite adjustment of d/p. In contrast, when d/p≤about 0.5, the fractional bandwidth can be increased to about 5% or higher if d/p is changed within the range, and thus, a resonator having a high coupling coefficient can be configured. Also, when d/p is about 0.24 or below, the fractional bandwidth can be increased to about 78 or higher. In addition, adjusting d/p within this range makes it possible to obtain a resonator with an even wider fractional bandwidth and thus achieve a resonator having an even higher coupling coefficient. This shows that, when d/p is, for example, about 0.5 or below, a resonator having a high coupling coefficient and using a bulk wave in thickness-shear mode can be configured.

FIG. 19 is a plan view of an acoustic wave device that uses a bulk wave in thickness-shear mode. In an acoustic wave device 80, an electrode pair including the electrode 3 and the electrode 4 is provided on the first main surface 2a of the piezoelectric layer 2. K in FIG. 19 is an intersecting width. As described above, in the acoustic wave devices of example embodiments of the present invention, there may be a single pair of electrodes. In this case as well, a bulk wave in thickness-shear mode can be effectively excited as long as d/p described above is, for example, about 0.5 or below.

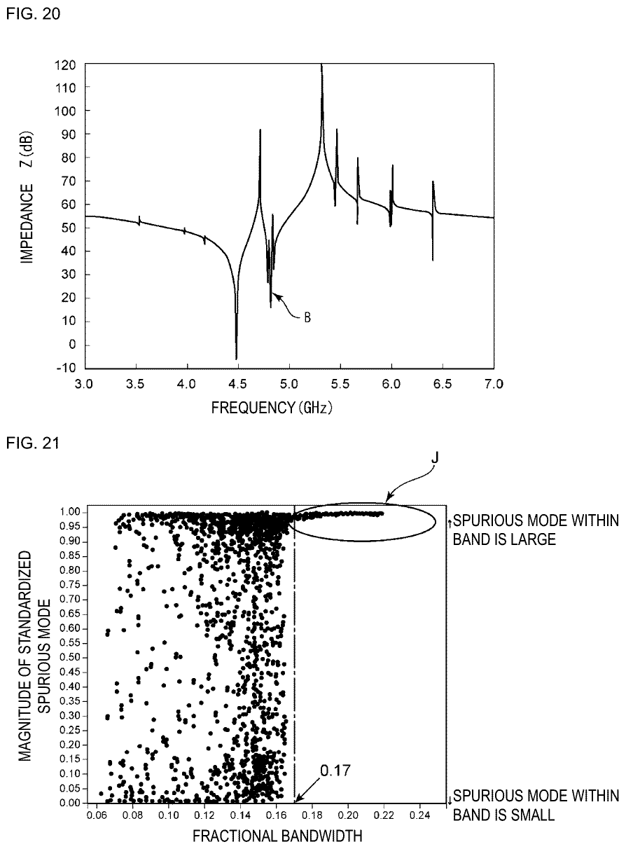

In the acoustic wave device 1, for example, it is preferable and desirable that a metallization ratio MR of any adjacent ones of the plurality of electrodes 3 and 4 to the excitation region C which is a region where the electrodes 3 and 4 adjacent to each other overlap when seen in the direction in which they face each other satisfy MR≤about 1.75 (d/p)+0.075. In that case, a spurious mode can be reduced effectively. This is described with reference to FIGS. 20 and 21. FIG. 20 is a reference diagram showing an example of the resonance characteristics of the acoustic wave device 1. The spurious mode indicated by the arrow B appears between the resonant frequency and the anti-resonant frequency. d/p=about 0.08, and LiNbO₃ with the Euler angles (0°, 0°, 90°) was used. Also, the above-described metallization ratio MR=about 0.35.

The metallization ratio MR is described with reference to FIG. 13B. In the electrode structure in FIG. 13B, focusing on a pair of electrodes 3 and 4, it is assumed here that only this pair of electrodes 3 and 4 is provided. In this case, the portion surrounded by the dot-dash line is the excitation region C. This excitation region C is a region in the electrode 3 overlapping with the electrode 4, a region in the electrode 4 overlapping with the electrode 3, and a region between the electrode 3 and the electrode 4 where the electrode 3 and the electrode 4 overlap each other, when the electrode 3 and the electrode 4 are seen in the direction orthogonal or substantially orthogonal to the length direction of the electrodes 3 and 4, i.e., the facing direction. Then, the area of the electrodes 3 and 4 inside the excitation region C in relation to the area of the excitation region C is the metallization ratio MR. Thus, the metallization ratio MR is the ratio of the area of the metallization part to the area of the excitation region C.

In a case where a plurality of pairs of electrodes are provided, the proportion of the metallization portions included in all of the excitation regions relative to the total area of the excitation regions is MR.

FIG. 21 is a diagram showing the relationship between the fractional bandwidth and the magnitude of a spurious mode, i.e., the amount of phase rotation of spurious impedance normalized by about 180°, in a case where a large number of acoustic wave resonators are configured according to the configuration of the acoustic wave device 1. The fractional bandwidth was adjusted by variously changing the film thickness of the piezoelectric layer and the dimensions of the electrodes. Also, although FIG. 21 shows results obtained when a piezoelectric layer made of Z-cut LiNbO₃ is used, the same or similar tendencies are observed when a piezoelectric layer with a different cut-angle is used.

A spurious mode is about 1.0 and large in the region surrounded by an oval J in FIG. 21. As is apparent from FIG. 21, when the fractional bandwidth exceeds about 0.17, i.e., exceeds about 17%, a large spurious mode with a spurious level of about 1 or greater appears in the pass band even if parameters forming the fractional bandwidth are changed. In other words, like the resonance characteristics shown in FIG. 20, a large spurious mode indicated by the arrow B appears within the band. It is therefore preferable that the fractional bandwidth is, for example, about 17% or below. In this case, a spurious mode can be reduced through adjustment of the thickness of the piezoelectric layer 2, the dimensions of the electrodes 3 and 4, and the like.

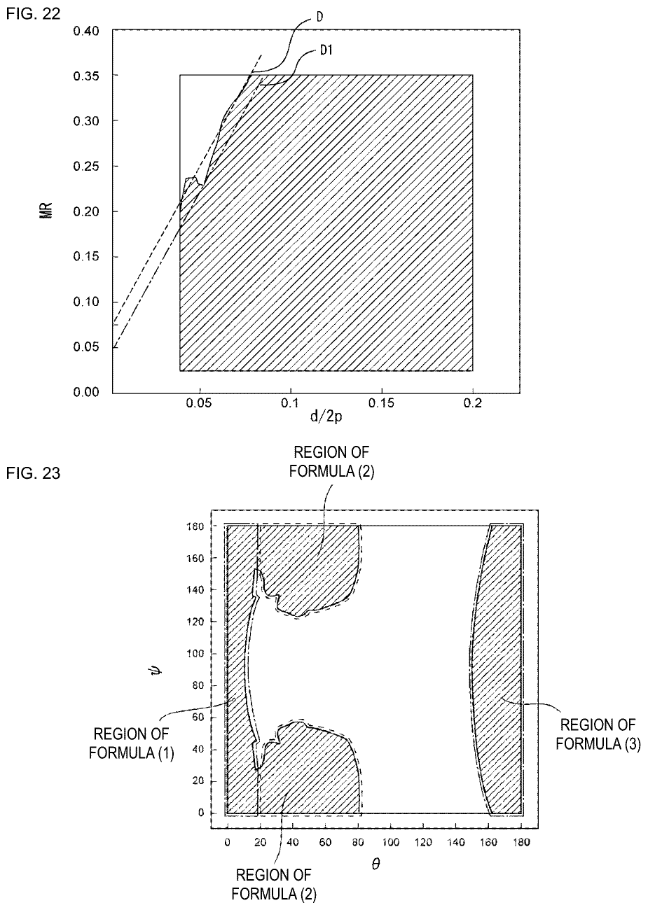

FIG. 22 is a diagram showing the relationship between d/2p, the metallization ratio MR, and the fractional bandwidth. With respect to the above-described acoustic wave device, various acoustic devices with different values of d/2p and MR were configured, and their fractional bandwidths were measured. The hatched portion on the right side of a broken line D in FIG. 22 is a region where the fractional bandwidth is about 17% or below. The border between this hatched region and the unhatched region is expressed by MR=about 3.5 (d/2p)+0.075. Thus, MR=about 1.75 (d/p)+0.075. Thus, for example, preferably, MR≤ about 1.75 (d/p)+0.075. In that case, the fractional bandwidth can be lowered to about 17% or below more easily. More preferably, for example, it is the region on the right side of the MR=about 3.5 (d/2p)+0.05, which is indicated by a dot-dash line D1 in FIG. 22. Thus, MR≤ about 1.75 (d/p)+0.05 ensures that the fractional bandwidth is about 17% or below.

FIG. 23 is a diagram showing the map of the fractional bandwidth in relationship to the Euler angles (0°, e, ¢) of LiNbO₃ when d/p is brought to almost zero. The hatched portions in FIG. 23 are regions where a fractional bandwidth of at least 5% or above is obtained, and approximating the ranges of these regions results in the ranges expressed by Formulae (1), (2), and (3) below.

$$( 0 ° \pm 10 ° , 0 ° to 20 ° , given ψ ) \qquad Formula ( 1 )$$

$$( 0 ° \pm 10 ° , 20 ° to 80 ° , 0 ° to 60 ° {( 1 - {( θ - 50 )}^{2} / 900 )}^{1 / 2} ) or \qquad Formula ( 2 )$$

$$( 0 ° \pm 10 ° , 20 ° to 80 ° , [ 180 ° - 60 ° {( 1 - {( θ - 50 )}^{2} / 900 )}^{1 / 2} ] to 180 ° )$$

$$( 0 ° \pm 10 ° , [ 180 ° - 30 ° {( 1 - {( ψ - 90 )}^{2} / 8100 )}^{1 / 2} ] to 180 ° ) , given ψ ) \qquad Formula ( 3 )$$

Thus, a sufficiently wide fractional bandwidth can be obtained by the ranges of the Euler angles of Formula (1), (2), or (3) described above, and thus, such ranges are preferable. This applies to a case where the piezoelectric layer 2 is a lithium tantalate layer, for example.

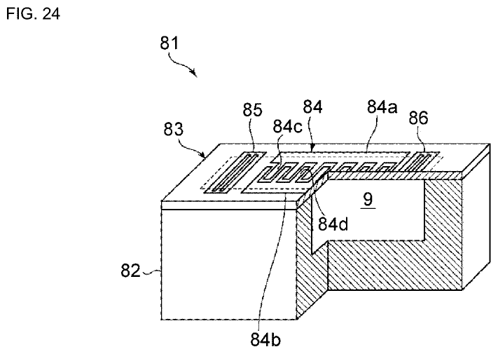

FIG. 24 is a partially cut-away perspective view illustrating an acoustic wave device that uses a Lamb wave.

An acoustic wave device 81 includes a support substrate 82. The support substrate 82 includes an open recess in an upper surface thereof. A piezoelectric layer 83 is laminated on the support substrate 82. The cavity portion 9 is thus provided. An IDT electrode 84 is provided on the piezoelectric layer 83, above the cavity portion 9. Reflectors 85 and 86 are provided at both sides of the IDT electrode 84 in the acoustic wave propagation direction. In FIG. 24, the outer edge of the cavity portion 9 is indicated with a broken line. In this device, the IDT electrode 84 includes first and second busbars 84a and 84b, a plurality of first electrode fingers 84c, and a plurality of second electrode fingers 84d. The plurality of first electrode fingers 84c are connected to the first busbar 84a. The plurality of second electrode fingers 84d are connected to the second busbar 84b. The plurality of first electrode fingers 84c and the plurality of second electrode fingers 84d are interdigitated with each other.

In the acoustic wave device 81, a Lamb wave as a plate wave is excited when an AC electric field is applied to the IDT electrode 84 on the cavity portion 9. Then, because the reflectors 85 and 86 are provided on the respective sides, resonance characteristics by the Lamb wave can be obtained.

In this way, an acoustic wave device according to an example embodiment of the present invention may use a plate wave. In the example shown in FIG. 24, the IDT electrode 84, the reflector 85, and the reflector 86 are provided on the main surface corresponding to the first main surface 14a of the piezoelectric layer 14 shown in FIG. 1 and the like. In a case where an acoustic wave device according to an example embodiment of the present invention uses a plate wave, for example, a functional electrode and the reflectors 85 and 86 shown in FIG. 24 are provided on the first main surface 14a of the piezoelectric layer 14 in the acoustic wave device of the first example embodiment or the second example embodiment. Alternatively, for example, the functional electrode 41 and the reflectors 85 and 86 shown in FIG. 24 are provided on the first main surface 14a and the second main surface 14b of the piezoelectric layer 14 in the acoustic wave device 40 of the third example embodiment.

As described above, d/p is, for example, preferably about 0.5 or below or more preferably about 0.24 or below in the acoustic wave devices of the first to third example embodiments or the modification that use a bulk wave in thickness-shear mode. Even more favorable resonance characteristics can thus be obtained.

The center-to-center distance p of adjacent ones of the first electrode fingers and the second electrode fingers in the IDT electrode corresponds to the center-to-center distance between adjacent ones of the first electrode fingers and the third electrode fingers or the center-to-center distance between adjacent ones of the second electrode fingers and the third electrode fingers in the first example embodiment and the like. Specifically, the longest one of the center-to-center distance between adjacent ones of the first electrode fingers and the third electrode fingers and the center-to-center distance between adjacent ones of the second electrode fingers and the third electrode fingers corresponds to the center-to-center distance p between adjacent ones of the first electrode fingers and the second electrode fingers in the IDT electrode. If the center-to-center distance between adjacent ones of the first electrode fingers and the third electrode fingers and the center-to-center distance between adjacent ones of the second electrode fingers and the third electrode fingers are the same, either one of these distances corresponds to the center-to-center distance p between adjacent ones of the first electrode fingers and the second electrode fingers in the IDT electrode.

Further, for example, it is preferable that, as described above, MR≤ about 1.75 (d/p)+0.075 is satisfied in the excitation region in any of the acoustic wave devices of the first to third example embodiments and the modification that use a bulk wave in thickness-shear mode. The metallization ratio of the first electrode finger and the second electrode finger in the IDT electrode corresponds to the metallization ratio of the first electrode finger and the third electrode finger as well as of the second electrode finger and the third electrode finger in the first example embodiment and the like. Thus, for example, it is preferable that MR≤ about 1.75 (d/p)+0.075 is satisfied where MR is the metallization ratio of the first electrode finger and the third electrode finger as well as of the second electrode finger and the third electrode finger in relationship to the excitation region. This further ensures reduction or prevention of a spurious mode.

The piezoelectric layer in the acoustic wave device that uses a bulk wave in thickness-shear mode in any of the first to third example embodiments and the modification is preferably a lithium niobate layer or a lithium tantalate layer, for example. Then, it is preferable that the Euler angles (φ, θ, ω) of the lithium niobate or lithium tantalate forming the piezoelectric layer be in the range of Formula (1), (2), or (3) given earlier. In this case, the fractional bandwidth can be sufficiently widened.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric layer including a first main surface and a second main surface facing each other;
at least one first electrode finger on the first main surface of the piezoelectric layer and connected to an input potential;
at least one second electrode finger on the first main surface of the piezoelectric layer and connected to an output potential; and
at least one third electrode finger on at least one of the first main surface and the second main surface of the piezoelectric layer and connected to a reference potential;
wherein the at least one first electrode finger and the at least one second electrode finger face each other when seen from an electrode finger orthogonal direction orthogonal or substantially orthogonal to a direction in which the first electrode finger and the second electrode finger extend;
a region where the at least one first electrode finger and the at least one second electrode finger adjacent to each other overlap in the electrode finger orthogonal direction is a facing region; and
the at least one third electrode finger overlaps with at least a portion of at least one facing region when seen from a main surface facing direction in which the first main surface and the second main surface of the piezoelectric layer face each other.

2. The acoustic wave device according to claim 1, wherein at least one of the at least one third electrode finger is provided on the first main surface of the piezoelectric layer.

3. The acoustic wave device according to claim 1, wherein at least one of the at least one third electrode finger is provided on the second main surface of the piezoelectric layer.

4. The acoustic wave device according to claim 1, further comprising a support overlapping with the piezoelectric layer when seen in the main surface facing direction.

5. The acoustic wave device according to claim 4, wherein
the support includes a cavity portion; and
when seen from the main surface facing direction, at least a portion of each of the at least one first electrode finger and the at least one second electrode finger overlaps with the cavity portion.

6. The acoustic wave device according to claim 5, wherein
the support includes a support substrate and an insulating layer; and
the cavity portion is provided in the insulating layer.

7. The acoustic wave device according to claim 1, wherein
at least one of the at least one first electrode finger and the at least one second electrode finger includes a plurality of electrode fingers; and
a plurality of the facing regions are provided.

8. The acoustic wave device according to claim 7, wherein
the at least one first electrode finger includes a plurality of first electrode fingers and the at least one second electrode finger includes a plurality of second electrode fingers;
the acoustic wave device further comprises:
a first busbar connected to the plurality of first electrode fingers; and
a second busbar connected to the plurality of second electrode fingers;
the plurality of first electrode fingers and the first busbar define a first comb-shaped electrode;
the plurality of second electrode fingers and the second busbar define a second comb-shaped electrode; and
the plurality of first electrode fingers and the plurality of second electrode fingers are interdigitated with each other.

9. The acoustic wave device according to claim 7, wherein
the third electrode finger includes a plurality of third electrode fingers; and
when seen from the main surface facing direction, the plurality of third electrode fingers are arranged in the electrode finger orthogonal direction.

10. The acoustic wave device according to claim 9, wherein, when seen from the main surface facing direction, at least two of the third electrode fingers are arranged consecutively in the electrode finger orthogonal direction and overlap with respective facing regions arranged consecutively in the electrode finger orthogonal direction among the plurality of facing regions.

11. The acoustic wave device according to claim 10, wherein, when seen from the main surface facing direction, three or more of the third electrode fingers are arranged consecutively in the electrode finger orthogonal direction and overlap with respective facing regions arranged consecutively in the electrode finger orthogonal direction among the plurality of facing regions.

12. The acoustic wave device according to claim 1, wherein the acoustic wave device is configured to generate a bulk wave in thickness-shear mode.

13. The acoustic wave device according to claim 1, wherein d/p is about 0.5 or below, where d is a thickness of the piezoelectric layer and p is a longest one of a center-to-center distance between the at least one first electrode finger and the at least one third electrode finger adjacent to each other when seen from the main surface facing direction and a center-to-center distance between the at least one second electrode finger and the at least one third electrode finger adjacent to each other when seen from the main surface facing direction.

14. The acoustic wave device according to claim 13, wherein d/p is about 0.24 or below.

15. The acoustic wave device according to claim 12, wherein
a region where the at least one first electrode finger and the at least one second electrode finger adjacent to each other directly or with the at least one third electrode finger interposed in between when seen from the main surface facing direction overlap in the electrode finger orthogonal direction is an excitation region; and
MR≤about 1.75 (d/p)+0.075 is satisfied, where MR is a metallization ratio of the at least one first electrode finger and the at least one third electrode finger and of the at least one second electrode finger and the at least one third electrode finger in relationship to the excitation region.

16. The acoustic wave device according to claim 1, wherein the piezoelectric layer includes lithium tantalate or lithium niobate.

17. The acoustic wave device according to claim 12, wherein
the piezoelectric layer includes lithium tantalate or lithium niobate;
Euler angles (φ, θ, ψ) of the lithium tantalate or lithium niobate of the piezoelectric layer are in ranges expressed by Formula (1), (2), or (3):
$$( 0 ° \pm 10 ° , 0 ° to 20 ° , given ψ ) ; \qquad Formula ( 1 )$$
$$( 0 ° \pm 10 ° , 20 ° to 80 ° , 0 ° to 60 ° {( 1 - {( θ - 50 )}^{2} / 900 )}^{1 / 2} ) or \qquad Formula ( 2 )$$
$$( 0 ° \pm 10 ° , 20 ° to 80 ° , [ 180 ° - 60 ° {( 1 - {( θ - 50 )}^{2} / 900 )}^{1 / 2} ] to 180 ° ) ; and$$
$$( 0 ° \pm 10 ° , [ 180 ° - 30 ° {( 1 - {( ψ - 90 )}^{2} / 8100 )}^{1 / 2} ] to 180 ° ) , given ψ ) . \qquad Formula ( 3 )$$

18. An acoustic wave filter device including at least one acoustic wave device according to claim 1.

19. The acoustic wave filter device according to claim 18, wherein at least one of the at least one third electrode finger is provided on the first main surface of the piezoelectric layer.

20. The acoustic wave filter device according to claim 18, wherein at least one of the at least one third electrode finger is provided on the second main surface of the piezoelectric layer.
